(19) United States
(12) Patent Application Publication
(10) Pub. No.: US 2017/0059799 A1
(43) Pub. Date: Mar. 2, 2017

(54) EMI SHIELDING OF AN OPTICAL PORT IN AN OPTICAL COMMUNICATIONS MODULE

(71) Applicant: Avago Technologies General IP (Singapore) Pte. Ltd, Singapore (SG)

(72) Inventors: Sanjeev Gupta, Santa Rosa, CA (US); Laurence McColloch, Santa Clara, CA (US)

(21) Appl. No.: 14/839,194

(22) Filed: Aug. 28, 2015

(51) Int. Cl. G02B 6/42; H05K 9/00; H05K 5/00

(52) U.S. Cl. CPC G02B 6/4277; G02B 6/428; H05K 5/0026; H05K 9/0058

(57) ABSTRACT

An optical communications module includes an upper housing portion mated to a lower housing portion, with one or more optical ports located inside the mated assembly. The one or more optical ports are accessible via respective openings in a front portion of the optical communications module. The lower housing portion accommodates an electronic circuit assembly that can lead to emission of electromagnetic interference (EMI) through the front portion of the optical communications module and particularly through the plastic walls of each optical port. Various exemplary embodiments of an electromagnetic interference (EMI) shield in accordance with the disclosure can be embedded inside the front plastic wall of each optical port in order to provide EMI shielding.

### FIELD OF THE INVENTION

The invention relates to EMI shielding, and more particularly, to an EMI shield that prevents EMI leakage from an optical port in an optical communications module.

### BACKGROUND

The U.S. Federal Communications Commission (FCC), which is one of several such similar organizations around the world, defines and enforces standards directed at limiting the amount of electromagnetic interference (EMI) emissions out of various electronic and electrical products. EMI emissions are generally undesirable as they can lead to malfunctioning of electronic and electrical products that are adversely impacted when exposed to interference from unwanted high frequency signals. However, it is difficult and expensive to provide EMI shielding elements that entirely eliminate EMI emissions out of products, such as, for example, optical communications modules.

The difficulty arises from challenges associated with creating EMI shielding elements that effectively conform to the individual shapes and sizes of assorted holes and openings located at various places in these products. EMI emissions can also take place directly through various non-metallic walls of an enclosure, such as for example, through one or more plastic walls of an optical communications module, or through one or more plastic walls of various objects contained inside the optical communications module.

Unfortunately, with the rise in operating data rates of circuits contained inside newer optical communications modules (and the resulting EMI emissions at significantly smaller wavelengths), various openings and holes that may have been acceptable in older optical communications modules can now turn out to be inappropriate because the size of one or more of these openings and holes may permit an unacceptable level of EMI leakage out of the newer optical communications modules.

It is therefore desirable to address at least some of the traditional shortcomings that are described above.

### BRIEF DESCRIPTION OF THE FIGURES

Many aspects of the invention can be better understood by referring to the following description in conjunction with the accompanying claims and figures Like numerals indicate like structural elements and features in the various figures. For clarity, not every element may be labeled with numerals in every figure. The drawings are not necessarily drawn to scale, emphasis instead being placed upon illustrating the principles of the invention. The drawings should not be interpreted as limiting the scope of the invention to the example embodiments shown herein.

FIG. 1 shows an exemplary embodiment of an optical communications module in accordance with the disclosure.

FIG. 2 shows a perspective view of an exemplary first optical port mounted in a lower housing portion of the optical communications module shown in FIG. 1.

FIG. 3 shows a perspective view of various exemplary components mounted in a lower housing portion of the optical communications module shown in FIG. 1.

FIG. 4 shows a perspective view of a molded body portion of the first optical port shown in FIG. 2 with a first exemplary EMI shield embedded in the optical port.

FIG. 5 shows a perspective view of the first exemplary EMI shield that is embedded in the first optical port shown in FIG. 4.

FIG. 6 shows another perspective view of the first exemplary EMI shield embedded in a plastic portion of the first optical port in accordance with the disclosure.

FIG. 7 shows a perspective view of a second exemplary EMI shield in accordance with the disclosure.

FIG. 8 shows a profile view of the second exemplary EMI shield shown in FIG. 6.

FIG. 9 shows a perspective view of a second exemplary optical port that can be mounted in a lower housing portion of the optical communications module shown in FIG. 1.

FIG. 10 shows a perspective view of a third exemplary EMI shield that is a part of the second exemplary optical port shown in FIG. 9.

FIG. 11 shows a perspective view of two of the second exemplary optical ports mounted in a lower housing portion of the optical communications module shown in FIG. 1.

### DETAILED DESCRIPTION

Throughout this description, embodiments and variations are described for the purpose of illustrating uses and implementations of inventive concepts. The illustrative description should be understood as presenting examples of inventive concepts, rather than as limiting the scope of the concept as disclosed herein. It should be further understood that certain words and terms are used herein solely for convenience and such words and terms should be interpreted as referring to various objects and actions that are generally understood in various forms and equivalencies by persons of ordinary skill in the art. For example, it should be understood that words such as “optical port” and “receptacle” generally refer to a portion of an optical communications module that is configured to provide mating with various external components such as, for example, an optical connector disposed at the end of an optical cable. It should also be understood that the word “example” as used herein is intended to be non-exclusionary and non-limiting in nature. More particularly, the word “exemplary” as used herein indicates one among several examples, and it must be understood that no undue emphasis or preference is being directed to the particular example being described.

Generally, in accordance with a first illustrative embodiment, an optical communications module includes an upper housing portion mated to a lower housing portion, with one or more optical ports located inside the mated assembly. The optical ports are accessible via respective openings in a front portion of the optical communications module. The lower housing portion accommodates an electronic circuit assembly that can lead to emission of electromagnetic interference (EMI) through the front portion of the optical communications module and particularly through the plastic walls of each optical port. Various exemplary embodiments of an electromagnetic interference (EMI) shield as disclosed herein, can be embedded inside the front plastic wall of each optical port in order to provide EMI shielding.

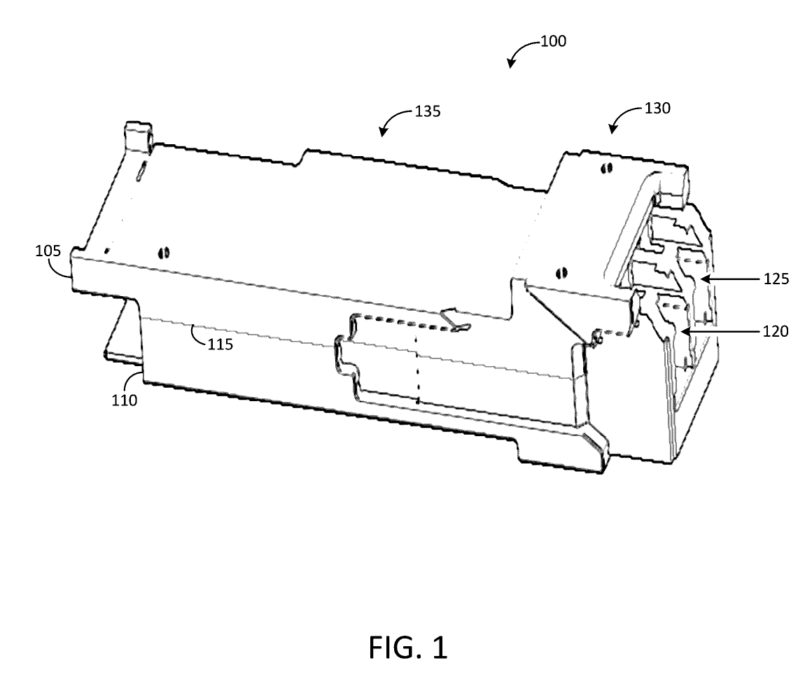

Attention is now drawn to FIG. 1, which shows an exemplary embodiment of an optical communications module 100. In accordance with this illustrative embodiment, the optical communications module 100 is a small form-factor pluggable (SFP) or enhanced SFP (SFP+) optical communications module. However, the invention is not limited to SFP or SFP+ optical communications modules and can be implemented in various other optical communications modules. The optical communications module 100 includes a front housing portion 130 coupled to a rear housing portion 135. The front housing portion 130 includes a first receptacle area 120 and a second receptacle area 125. The first receptacle area 120 provides room for connecting a first optical cable or other connection element to a first optical port (not shown). The second receptacle area 125 provides room for connecting a second optical cable or other connection element to a second optical port (not shown). In accordance with this illustrative embodiment, the first and second optical ports are configured or adapted to mate with LC optical connectors disposed on the ends of respective optical cables, although the invention is not limited in regard to the types of optical connectors. The rear housing portion 135 of the optical communications module 100 includes a lower housing portion 110 and an upper housing portion 105. In this example implementation, each of the lower housing portion 110 and the upper housing portion 105 is made entirely, or partially, of metal, although non-metallic materials such as plastic can also be used. The lower housing portion 110 and the upper housing 105 can be provided in the form of a pivot and snap feature that allows the two portions to be mated with each together.

EMI leakage can take place out of various openings in the optical communications module 100. One area of the optical communications module 100 that is particularly vulnerable to EMI emissions is the first receptacle area 120 and the second receptacle area 125.

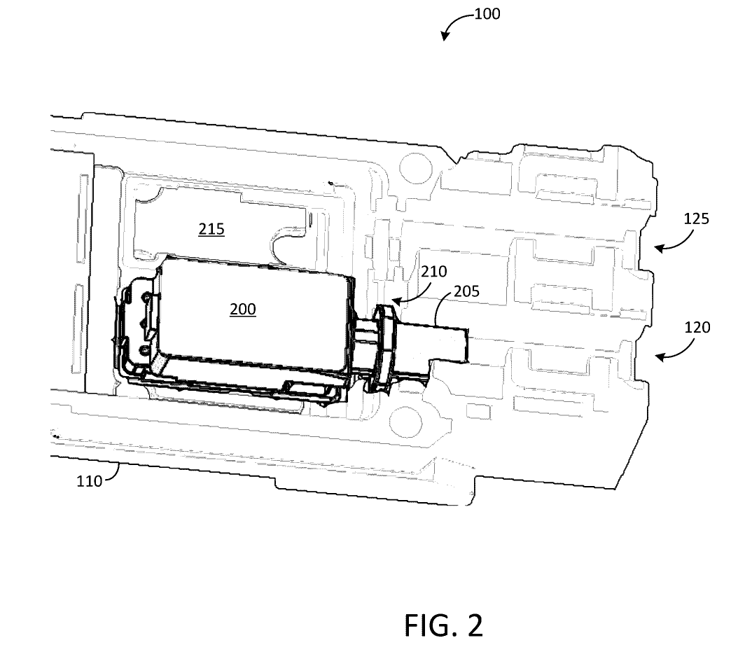

FIG. 2 shows a perspective view of an exemplary optical port 200 mounted in the lower housing portion 110 of the optical communications module 100 that is shown in FIG. 1. A second optical port (not shown) can be accommodated in the area 215 but has been omitted in FIG. 2 in the interest of brevity, because the description provided herein with respect to the optical port 200 can be applied to the second optical port as well.

A cylindrical body 205 of the optical port 200 projects out into the first receptacle area 120 through a circular opening 210. In this exemplary embodiment, the circular opening 210 is formed by abutting a semicircular opening provided in a wall of the upper housing portion 105 with a corresponding semicircular opening provided in a wall of the lower housing portion 110.

In view of manufacturing tolerances and other factors, a first gap can exist between the cylindrical body portion of the optical port 200 and the inner periphery of the circular opening 210. EMI emissions can leak out of the optical communications module 100 not only through the circular opening 210 but through other gaps, such as, for example, the gap 115 (FIG. 1) where the upper housing portion 105 abuts the lower housing portion 110. EMI emissions can also directly leak out of various walls in the optical communications module 100 when electronic circuitry contained inside the optical communications module 100 is operated at higher regions of the frequency spectrum, such as, for example, at microwave frequencies.

For example, in one example implementation, the optical communications module 100 may contain electronic circuitry operating in the Gigahertz (GHz) range of frequencies. Such frequencies can readily propagate out of non-metallic surfaces as well as some ungrounded metallic surfaces. It is therefore desirable that EMI shielding be provided to intercept EMI emissions taking place through one or more openings in the optical port 200 and conduct the intercepted EMI emissions to ground.

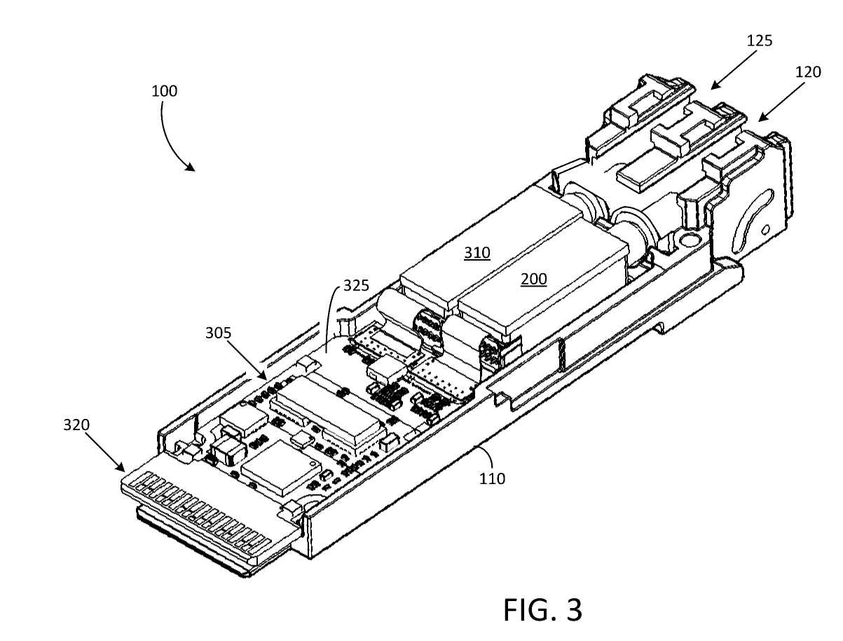

FIG. 3 shows a first perspective view of various exemplary components mounted in the lower housing portion 110 of the optical communications module 100. The various exemplary components include an electronic circuit assembly 305, the first optical port 200, and a second optical port 310. The electronic circuit assembly 305 includes various components that operate upon electrical signals of various frequencies. When these frequencies correspond to higher regions of the frequency spectrum, for example, GHz frequencies, EMI emissions can take place out of one or more components of the electronic circuit assembly 305. The EMI emissions can radiate out in various directions, including towards the first receptacle area 120 and the second receptacle area 125.

The optical communications module 100 includes an electronic circuit assembly 305. In this illustrative embodiment, the various components of the electronic circuit assembly 305 are mounted on a printed circuit board (PCB) 325. In exemplary implementations, the various components mounted on the PCB 325 can operate at high data rates, thus leading to emission of short wavelength EMI signals. The PCB 325 can be a multilayer PCB and include a ground layer. The ground layer is connected to a set of ground pins that are a part of an edge connector 320. The edge connector 320 has other pins that are connected to various other components of the electronic circuit assembly 305 for purposes of conducting various electrical signals that are operated upon by the electronic circuit assembly 305.

When the optical communications module 100 is inserted into a host device (not shown) such as a router or a communications switch, the edge connector 320 mates with a corresponding connector in the host device. Each of the set of ground pins that are a part of the edge connector 320 makes contact with a matching set of ground pins in the corresponding connector of the host device.

An EMI shield (not shown) embedded in each of the first optical port 200 and the second optical port 310 is connected to ground via one or more metallic contact portions of the lower housing portion 110 and the upper housing portion 105, thereby maintaining each EMI shield at ground potential and suppressing EMI emissions radiating from the electronic circuit assembly 305 as well as any EMI emissions that may radiate out of the first optical port 200. Further details pertaining to various exemplary EMI shields that can be used for this purpose are described below with reference to other figures.

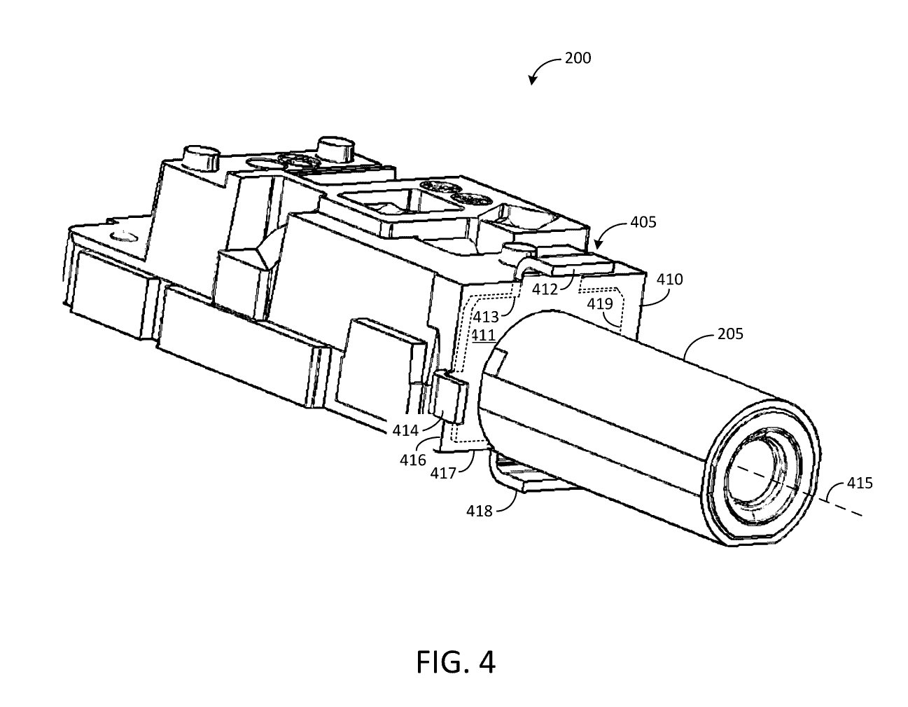

FIG. 4 shows a perspective view of a molded body portion of the optical port 200 with a first exemplary EMI shield 405 embedded in a plastic portion 410. The cylindrical body 205 projects out into the first receptacle area 120 of the optical communications module 100 as shown in FIG. 2. The EMI shield 405 can be fabricated as a metal lead frame having a planar portion 411 that is embedded inside the plastic portion 410. The planar portion 411 of the EMI shield 405 is oriented orthogonal to an optical axis 415 of the optical port 200 and has a number of holes (not shown) including a central hole through which light can pass into, or out of, the optical port 200. Even though light can propagate through the central hole in the EMI shield 405, the central hole, as well as the other holes, are explicitly sized in accordance with the disclosure so as to prevent, or at least minimize, the propagation of EMI radiation out of the optical communications module 100 though the first receptacle area 120 and the second receptacle area 125. Further details pertaining to the EMI shield 405 are described below with respect to other figures.

The EMI shield 405 can further include one or more protrusions on one or more peripheral edges. In this example implementation, a first protrusion 412 on a first peripheral edge 413 of the EMI shield 405 extends in an orthogonal direction away from the planar portion 411. A second protrusion 414 on a second peripheral edge 416 of the EMI shield 405 extends in an orthogonal direction away from the planar portion 411. A third protrusion 418 on a third peripheral edge 417 of the EMI shield 405 extends in an orthogonal direction away from the planar portion 411. A fourth protrusion (not shown) on a fourth peripheral edge 419 of the EMI shield 405 extends in an orthogonal direction away from the planar portion 411.

In this example implementation, each of the four protrusions is a flat, rectangular-shaped finger formed by bending a fractional portion of a respective peripheral edge. In other implementations, other variants of such protrusions can be provided. For example, less than four protrusions may be provided, one or more of the protrusions can extend at an angle other than 90 degrees with respect to the planar portion 411, and/or one or more of the protrusions can be coplanar with respect to the planar portion 411. Furthermore, one or more of the protrusions can have a shape other than a rectangular finger, such as, for example, a finger with rounded corners, or a finger with one or more bends.

Irrespective of the nature of the protrusions, one or more of the first protrusion 412, the second protrusion 414, the third protrusion 418, or the fourth protrusion (not shown) makes contact with a metal portion of the optical communications module 100 when the first optical port 200 is housed inside the optical communications module 100. This contact arrangement permits any EMI currents that are generated in the EMI shield 405 as a result of intercepting EMI emissions emanating from inside the optical communications module 100, to be conducted to ground.

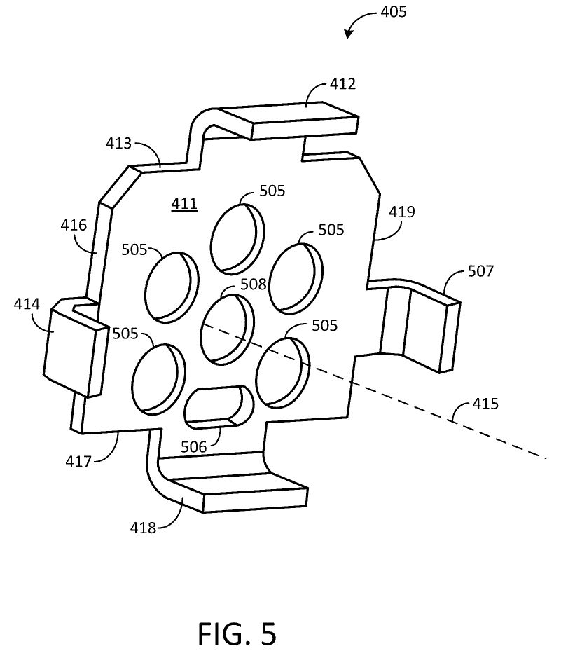

FIG. 5 shows a perspective view of the first exemplary EMI shield 405 that is embedded in the molded body portion of the optical port 200 shown in FIG. 4. A fourth protrusion 507, which was not shown in FIG. 4, is shown in FIG. 5 on the fourth peripheral edge 419. A respective width of each of the first protrusion 412, the second protrusion 414, the third protrusion 418, and the fourth protrusion 507 can be equal in one example implementation, and different in another example implementation. Also, the angle at which one or more of the first protrusion 412, the second protrusion 414, the third protrusion 418, and the fourth protrusion 507 protrudes from the planar portion 411 and/or the direction of the protrusion, can be identical in one example implementation, and different in another example implementation.

The EMI shield 405 is manufactured as a metal lead frame and can be embedded in the optical port 200 using various manufacturing procedures. In one example manufacturing procedure, the metal lead frame is stamped in a carrier strip having multiple similar metal lead frames. An indexing procedure is then used to position the carrier strip in a mold, followed by filling the mold with plastic. After molding is completed, a cutting procedure is executed, leaving the protrusions extending outwards from the plastic body of a first optical port connected to a neighboring protrusion from another optical port. A singulating procedure is then used to separate each optical port from a neighboring optical port. Each protrusion is then bent in accordance with the illustrative embodiment shown in FIG. 5.

Irrespective of the manner in which the part is manufactured, the EMI shield 405 includes a number of holes in the planar portion 411. Two or more of these holes can be identical to each other in one example implementation, and different from each other in another example implementation. In the exemplary embodiment shown in FIG. 5, the planar portion 411 includes a central hole 508, an oval hole 506, and five additional holes 505. In other embodiments, any number of holes in addition to the central hole 508 can be used, and the holes can have various shapes other than the circular and oval shapes shown in this exemplary embodiment.

Among various factors that can be used for determining the size and shape of the central hole 508, a first factor pertains to providing unimpeded optical transmission along the optical axis 415. The first factor is an important factor as it addresses a primary functionality of the optical communications module 100. A second factor can be a manufacturing-related factor, for example, one that is directed at accommodating a flow of plastic material through the central hole 508, as well as through the other holes, when the optical port 200 is fabricated using a plastic molding procedure. A third factor can be an operations-related factor wherein the size of some or all holes is determined on the basis of an EMI frequency or EMI bandwidth. The EMI frequency or EMI bandwidth, is typically associated with circuit operation of the electronic circuit assembly 305. For example, a first EMI frequency or EMI bandwidth, can be used for calculating the size of some or all holes when the electronic circuit assembly 305 is designed to operate at a first high speed data rate. The first high speed data rate can be characterized in various ways, such as, for example, by a first microwave frequency (a fundamental frequency, for example) or by a first band of microwave frequencies. A different EMI frequency or EMI bandwidth can be used for calculating the size of some or all holes when the electronic circuit assembly 305 is designed to operate at a second high speed data rate. The second high speed data rate can be characterized by a different microwave frequency (a different fundamental frequency, for example) or by a different band of microwave frequencies.

One or more wavelengths corresponding to the determined EMI frequency or EMI bandwidth can be used to calculate a desired size of some or all of the holes. For example, a fraction of a wavelength in say, nanometers, may be used to define a desired size of some or all holes.

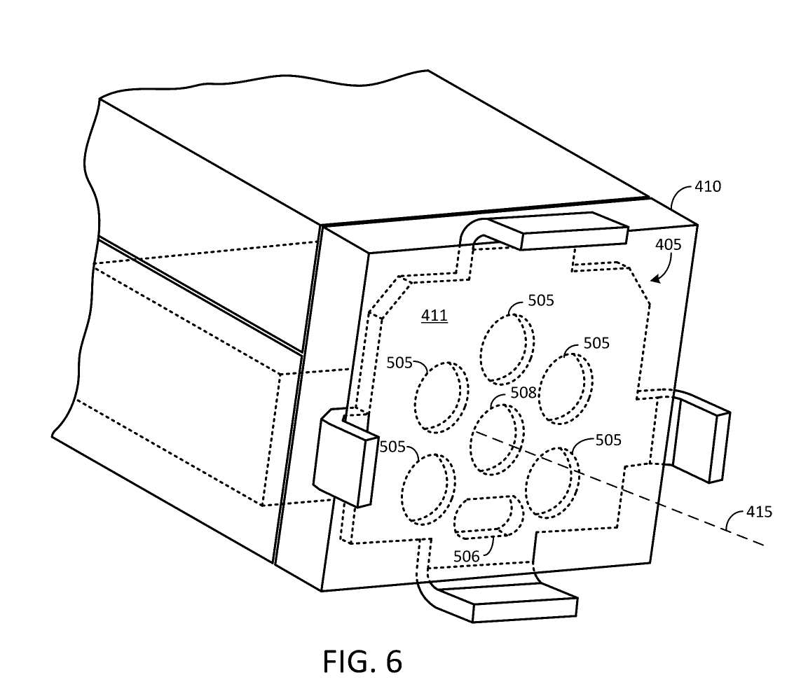

FIG. 6 shows a perspective view of the first exemplary EMI shield 405 embedded in the plastic portion 410 of the optical port 200. Specifically, the planar portion 411, which is oriented orthogonal to the optical axis 415 of the optical port 200, includes the various holes that have been described above. The plastic portion 410 of the optical port 200 can be fabricated as an independent part and then assembled together with other parts of the optical port 200, or can be fabricated as an integrated part of the optical port 200.

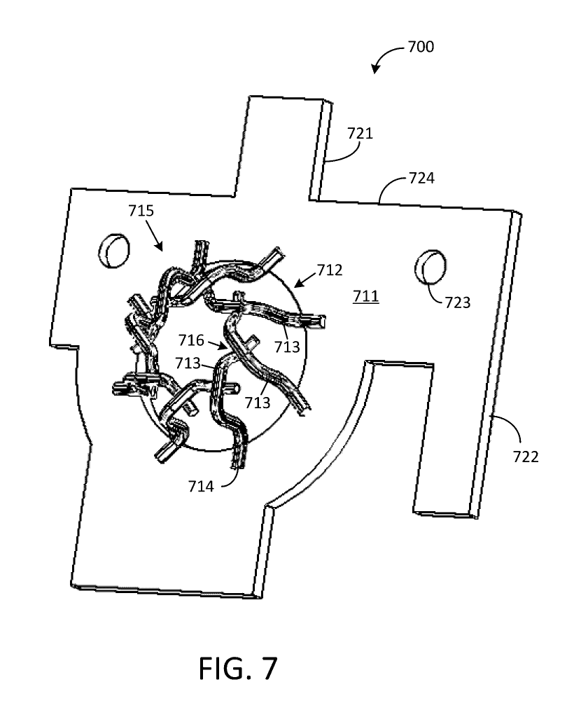

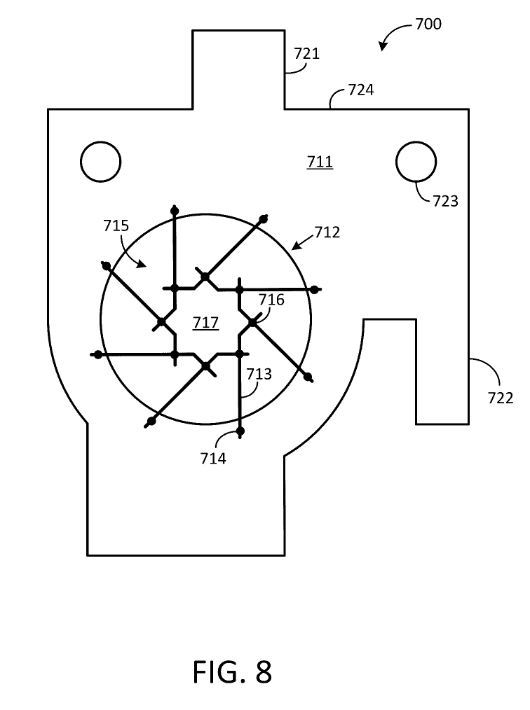

Attention is next drawn to FIG. 7, which shows a perspective view of a second exemplary EMI shield 700 in accordance with the disclosure and also to FIG. 8, which shows a profile view of the second exemplary EMI shield 700. The EMI shield 700 can be fabricated as a metal lead frame having a planar portion 711 that can be embedded inside the plastic portion 410 of the optical port 200 described above. The planar portion 711, which is oriented orthogonal to the optical axis 415 of the optical port 200, has a hole 712 through which light can pass into, and out of, the optical port 200. The planar portion 711 includes a plurality of wire forms arranged in a mesh configuration 715 over the hole 712 for intercepting electromagnetic interference (EMI) emissions propagating out of the optical communications module 100 through the hole 712. The mesh configuration 715 is formed by a number of wire forms each of which extends angularly over the hole 712. Specifically, a distal end 714 of each wire form 713 is anchored on the planar portion 711 along a periphery portion of the hole 712 and a proximal end 716 is secured to a neighboring wire form over the hole 712. An intermediate portion of each wire form 713 can be anchored to a second neighboring wire form. The anchoring can be executed by a welding process, a soldering process, or any other such processes.

The mesh configuration 715 provides a substantially star-shaped central opening 717 with a central vertex of the star-shaped central opening 717 aligned with a central vertex of the hole 712, which is a circular hole in the illustrative implementation shown in FIGS. 7 and 8. The wire forms that constitute the mesh configuration 715 consume little space in comparison to an element that incorporates a solid surface containing holes (such as a metal plate having holes, for example), while providing operability as an EMI shield. Additionally, a material such as plastic can readily flow through the mesh configuration 715 when a molding process is employed for embedding the EMI shield 700 in an optical port, such as, for example, the optical port 200 described above.

In the illustrative implementation shown in FIG. 7, each wire form 713 includes a U-shaped portion that extends away from the planar portion 711. In other implementations, the U-shaped portion can be eliminated or can be replaced by other shapes.

The size of the star-shaped central opening 717 can be selected on the basis of various factors. One among these various factors can be a manufacturing related factor, for example, one that is directed at accommodating a flow of plastic material through the star-shaped central opening 717 and other openings in the mesh configuration 715 when the optical port 200 is fabricated using a plastic molding procedure. Another factor among the various factors is an operating performance related factor. For example, size of the star-shaped central opening 717 and other openings in the mesh configuration 715 can be selected on the basis of a frequency of operation of the electronic circuit assembly 305 contained inside the optical communications module 100. Specifically, one or more of these openings can be selected to correspond to a fraction of a wavelength corresponding to the frequency of operation of the electronic circuit assembly 305 such that EMI radiation at the frequency of operation is effectively intercepted by the mesh configuration 715.

The EMI shield 700 not only includes the planar portion 711, but further includes several protrusions on one or more peripheral edges. In this example implementation, a first protrusion 721 on a first peripheral edge 724 of the EMI shield 700 is an extension of a portion of the planar portion 411. A second protrusion 722 is an extension of a portion of the planar portion 411 with a different orientation and dimension. The planar portion 411 can further include one or more holes such as a hole 723. The hole 723 can be used for various purposes, such as, for example, aligning the EMI shield 700 when embedding the EMI shield 700 in plastic.

In other implementations, other variants of such protrusions can be provided. For example, one or more of the protrusions can extend at an angle, such as, for example, 90 degrees, with respect to the planar portion 711. Furthermore, one or more of the protrusions can have a shape other than a rectangular finger, such as, for example, a finger with rounded corners, or a finger with one or more bends.

Irrespective of the nature of the protrusions, one or more of the first protrusion 721 and the second protrusion 722 makes contact with a metal portion of the optical communications module 100 when the first optical port 200 is housed inside the optical communications module 100. This contact arrangement permits any EMI currents that are generated in the EMI shield 700 as a result of intercepting EMI emissions emanating from inside the optical communications module 100, to be conducted to ground.

Integrating multiple wire forms on to the EMI shield 700, in the form of the mesh configuration 715 provides various manufacturing advantages, such as, for example, eliminating the handling of individual wire forms and placing these individual wire forms in a one-by-one manner inside plastic material when manufacturing an optical port.

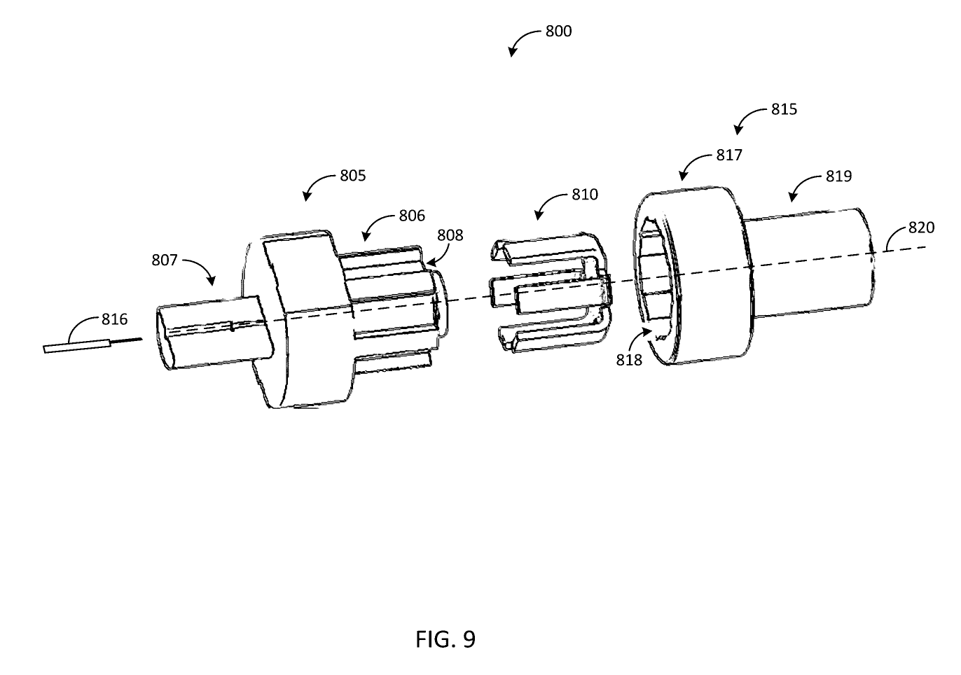

Attention is next drawn to FIG. 9, which shows a perspective view of a second exemplary optical port 800 that can be mounted in the lower housing portion 110 (FIG. 1) of the optical communications module 100 (FIG. 1). The second exemplary optical port 800 is a multi-component assembly that has an EMI shield 810 disposed between a first mating element 805 and a second mating element 815. The structure of the optical port 800 provides several advantages. For example, each of the three components can be manufactured independent of the other two components, thereby eliminating the need for a complex, automated mold that is typically employed for insert molding purposes. For example, each of the first mating element 805 and the second mating element 815 can be manufactured using a mold for molding plastic components and the EMI shield 810 can be manufactured separately using a metal stamping process at a different time and place if so desired. Furthermore, assembling these independently manufactured component to form the optical port 800 is a relatively simple procedure that does not require complicated assembling equipment.

In this example embodiment, the optical port 800 is configured as a fiber stub assembly that accepts placement of an optical fiber 816 in a notched portion of an input section 807 of the first mating element 805. Light propagating into, or out of, the optical fiber 816 travels along an optical axis 820 that extends along a length of the optical port 800. The first mating element 805 includes an output section 806 that is substantially cylindrical in shape and includes a number of grooves located on an outer surface of the output section 806. Each groove, such as a groove 808 extends parallel to the optical axis 820. The second mating element 815 includes an input section 817 that is substantially cylindrical in shape and includes a number of grooves located on an inner surface of the input section 817. Each groove, such as a grove 818, extends parallel to the optical axis 820.

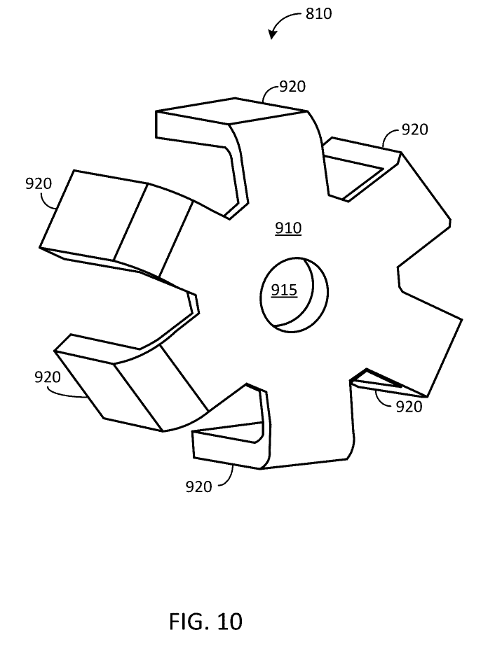

FIG. 10 shows a perspective view of the EMI shield 810 that is a part of the exemplary optical port 800 shown in FIG. 9. The EMI shield 810 has a circular planar portion 910 that includes a centrally-located hole 915 through which light propagates along the optical axis 820, as can be understood from FIG. 9. In the illustrative implementation shown in FIGS. 9 and 10, the centrally-located hole 915 is a circular hole. The dimension of this circular hole can be selected on the basis of various factors, such as, for example, on the basis of a wavelength of operation of the electronic circuit assembly 305 (FIG. 3) contained inside the optical communications module 100. Thus, for example, a diameter of the circular hole can be set equal to a fraction of a wavelength whereby EMI radiation is effectively intercepted by the EMI shield 810. In one exemplary implementation, the diameter of the centrally-located hole 915 can be about 0.6 mm.

The EMI shield 810 further includes a number of fingers located along a periphery portion of the circular planar portion 910, each finger 920 extending away from a major surface of the circular planar portion 910 and parallel to the optical axis 820. When the EMI shield 810 is press-fitted on to the output section 806 of the first mating element 805, an inner surface of each finger 920 nestles into a respective groove in the multiple grooves located on the outer surface of the output section 806. The second mating element 815 is further press-fitted on to the EMI shield 810 such that a first portion of an outer surface of each finger 920 nestles into a respective groove in the multiple grooves located on the inner surface of the input section 817 that is a part of the second mating element 815.

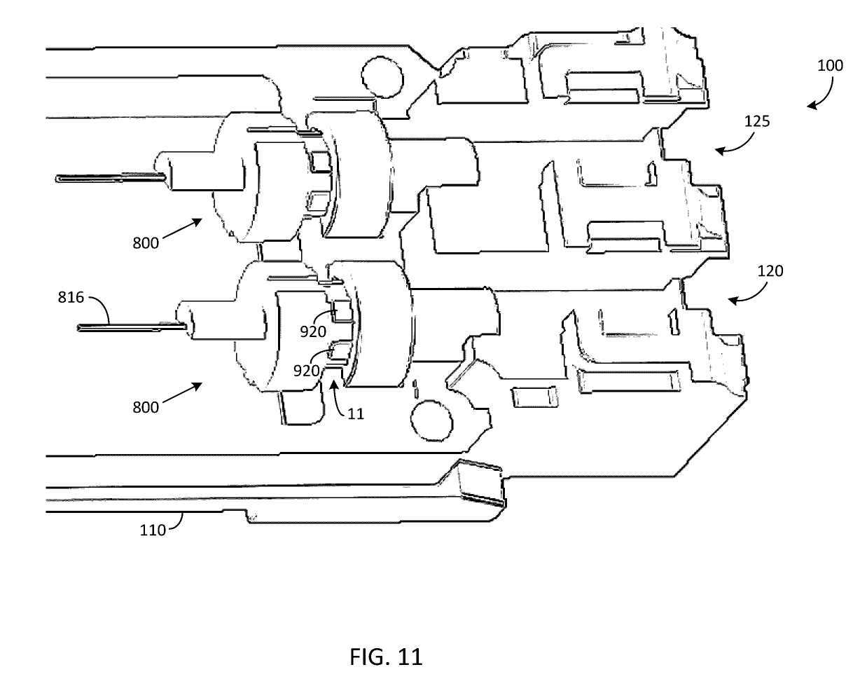

FIG. 11 shows a perspective view of two exemplary optical ports 800 mounted in the lower housing portion 110 of the optical communications module 100. Attention is drawn to an exposed metal portion 11 in each of the two exemplary optical ports 800. The exposed metal portion 11 corresponds to a second portion of the outer surface of each finger 920 (FIG. 10) of the EMI shield 810. As described above, a first portion of an outer surface of each finger 920 nestles into a respective groove in the various grooves located on the inner surface of the input section 817 that is a part of the second mating element 815.

When the lower housing portion 110 of the optical communications module 100 is assembled with the upper housing portion 105 (FIG. 1), the exposed metal portion 11 comes in contact with metal portions of each of the lower housing portion 110 and the upper housing portion 105, thus providing ground connectivity to the EMI shield 810.

In summary, it should be noted that the invention has been described with reference to a few illustrative embodiments for the purpose of demonstrating the principles and concepts of the invention. It will be understood by persons of skill in the art, in view of the description provided herein, that the invention is not limited to these illustrative embodiments. Persons of skill in the art will understand that many such variations can be made to the illustrative embodiments without deviating from the scope of the invention.

What is claimed is:

1. An optical communications module, comprising:
a case; and
an optical port located inside the case, the optical port having a metal lead frame operative as an electromagnetic interference (EMI) shield, the metal lead frame having a planar portion that is embedded in a plastic body of the optical port and is oriented orthogonal to an optical axis of the optical port for intercepting at least a portion of EMI emissions that are parallel to the optical axis, the planar portion having a plurality of holes formed therein, the plurality of openings including a central hole having a size that is selected to allow light propagation along the optical axis.

2. The optical communications module of claim 1, wherein the metal lead frame has a protrusion on at least one peripheral edge, the protrusion extending out of the plastic body of the optical port.

3. The optical communications module of claim 2, wherein the protrusion constitutes a fractional portion of the at least one peripheral edge and wherein the fractional portion extends away at an angle from a major surface of the planar portion.

4. The optical communications module of claim 3, wherein the metal lead frame is a four-sided metal frame and each of the peripheral edges of the four-sided metal frame includes the protrusion, and wherein the protrusion extends away substantially orthogonal to the major surface of the planar portion.

5. The optical communications module of claim 4, wherein protrusion extending out of the plastic body of the optical port is configured to provide contact with one or more metal portions of the case for connectivity to ground potential.

6. The optical communications module of claim 1, wherein the size of each of the plurality of openings is selected to accommodate passage of a plastic material through each of the plurality of openings when the planar portion of the metal lead frame is embedded in the plastic body of the optical port by molding.

7. The optical communications module of claim 1, further comprising:
an EMI source housed inside the case, the EMI source comprising electronic circuit elements.

8. An optical communications module, comprising:
a case; and
an optical port located inside the case, the optical port comprising a metal lead frame having a planar portion embedded in a plastic body of the optical port, the planar portion oriented orthogonal to an optical axis of the optical port and having a hole configured to allow propagation of light along the optical axis, the planar portion further comprising a plurality of wire forms arranged in a mesh configuration over the hole for intercepting electromagnetic interference (EMI) emissions propagating out of the case through the hole.

9. The optical communications module of claim 8, wherein the mesh configuration comprises each wire form angularly extending towards an internal portion of the hole with a distal end secured to a perimeter portion of the hole and a proximal end secured to a neighboring wire form over the hole.

10. The optical communications module of claim 9, wherein the hole is a circular hole and wherein the mesh arrangement includes a substantially star-shaped central opening that is axially aligned with a central vertex of the circular hole.

11. The optical communications module of claim 10, wherein a diameter of the circular hole is about twice as large as a diameter of the star-shaped opening in the mesh configuration.

12. The optical communications module of claim 9, wherein each wire form includes a U-shaped portion that extends away from the planar portion.

13. The optical communications module of claim 12, wherein the proximal end of each wire form is secured to the neighboring wire form at the U-shape portion of the neighboring wire form.

14. The optical communications module of claim 8, wherein the planar portion of the metal lead frame includes at least one protrusion exposed outside the plastic body of the optical port, the at least one protrusion configured to provide contact with a metal portion of the case for connectivity to ground potential.

15. An optical communications module, comprising:
a case; and
an optical port located inside the case, the optical port comprising:
a first mating element that includes a cylindrical body configured to allow propagation of light traveling along an optical axis of the optical port, the first mating element further including a plurality of grooves arranged around an external surface of the cylindrical body, each of the plurality of grooves extending longitudinally along the cylindrical body and parallel to the optical axis; and
an electromagnetic interference (EMI) metal shield that includes a circular planar portion oriented orthogonal to the optical axis of the optical port and having a hole to allow propagation of light traveling along the optical axis, the EMI metal shield further including a plurality of fingers located along a periphery of the circular portion, each of the plurality of fingers extending away from a major surface of the circular planar portion and parallel to the optical axis, each of the plurality of fingers configured to be located in a respective groove of the plurality of grooves on the external surface of the cylindrical portion of the first mating element when the EMI metal shield is engaged upon the first mating element.

16. The optical port of claim 15, further comprising:
a second mating element that includes a hollow portion configured to at least partially enclose the EMI metal shield when the second mating element is mated to the first mating element after the EMI metal shield is engaged upon the first mating element.

17. The optical port of claim 16, wherein when the hollow portion of the second mating element partially encloses the EMI metal shield, an exposed portion of each of the plurality of fingers of the EMI metal shield provides contact with one or more metal portions of the case for connectivity to ground potential.

18. The optical port of claim 16, wherein the hole in the circular planar portion of the EMI shield is a circular hole having a diameter that is less than a diameter of the cylindrical body of the first mating element.

19. The optical port of claim 16, wherein the EMI metal shield is a stamped metal part.

20. The optical communications module of claim 19, further comprising:
an EMI source housed inside the case, the EMI source comprising electronic circuit elements.
